(19) United States
(12) Patent Application Publication
(10) Pub. No.: US 2010/0126555 A1
(43) Pub. Date: May 27, 2010

(54) CONCENTRATING PHOTOVOLTAIC PHOTO-CURRENT BALANCING SYSTEM

(75) Inventor: Patrick M. MAXTON, San Jose, CA (US)

Correspondence Address: MORRISON & FOERSTER LLP, 755 PAGE MILL RD, PALO ALTO, CA, 94304-1018, US

(73) Assignee: Hoozad Inc., San Francisco, CA (US)

(21) Appl. No.: 12/622,331

(22) Filed: Nov. 19, 2009

Related U.S. Application Data
(60) Provisional application No. 61/199,769, filed on Nov. 20, 2008.
(60) Provisional application No. 61/200,453, filed on Nov. 28, 2008.

(51) Int. Cl. H01L 31/042

(52) U.S. Cl. 136/246; 136/244

(57) ABSTRACT

A solar cell concentrating apparatus includes a parabolic reflector focusing a beam of light on an array of photovoltaic cells to generate electric current. The photocell array includes a number of triangular shaped segments arranged in a polygon. Surrounding the triangular shaped segments is another set of solar cells, each having a trapezoidal shape. The trapezoidal cells each have a larger surface area than that of the adjacent triangular shaped cell. The electric current produced by each trapezoidal cell is approximately the same as that of the smaller triangular shaped cells, which are subject to more intense incident light due to the beam's Gaussian spot profile.

### CROSS-REFERENCE TO RELATED APPLICATIONS

This application claims priority to U.S. Provisional Application Nos. 61/199,769, filed Nov. 20, 2008, and 61/200,453, filed Nov. 28, 2008 incorporated herein by reference in their entirety.

### FIELD OF THE INVENTION

This disclosure relates to generation of electricity by means of photovoltaic cells and more particularly to a concentrator apparatus whereby sunlight is concentrated on an array of photovoltaic cells.

### BACKGROUND

Concentrating photovoltaic apparatuses are well known in the field of electric current generation. See for instance WO2009/002281A2 published Dec. 31, 2008, inventor Jan ZUPA, disclosing a parabolic concentrating photovoltaic converter illustrated in a perspective view in present FIG. 1. This includes a large offset parabolic assembly of a number of rectangular shaped mirrors 3 with a concentrating photovoltaic (solar) cell array 7 in the focusing area of the mirror assembly. A base 13 is provided; struts 11 support the cell array 7.

FIG. 2 illustrates in somewhat a schematic fashion a cross-sectional view of a similar solar concentrating apparatus disclosed in U.S. Patent Publication US2009/0032103A1 published Feb. 5, 2009, inventor Binxuan Y I. This includes a plurality of solar cells 21 mounted on a support 22. Support 22 is on the center of a parabolic shaped mirror base 23 which is rotationally symmetric about axis A-A. The parabolic mirror base 23 includes a large number of relatively small plane mirrors 26 mounted on the inner side of the mirror base 23. The mirrors are, e.g., one inch (2.54 cm) square in one embodiment. The solar cells 21 are arranged around a focus point of reflected light rays from the plane mirrors 26. A number of heat sinks 24 are provided on the outer side of the mirror base 23 for cooling purposes. This apparatus is somewhat smaller in size than that of FIG. 1, but otherwise similar. Both the above patent publications are incorporated herein by reference in their entireties.

In this field, a typical reflector assembly size is 0.75 to 10 meters in diameter, but this is not limiting. Such arrangements are generally well known in a number of variations. For instance, some mirror assemblies include a large number of small planar mirrors as described above. In other cases the mirror assembly is a single reflective surface parabolic bowl. Both are well known to exhibit undesirable optical non-uniformities due to material and manufacturing variations.

### SUMMARY

There are several deficiencies with such photovoltaic concentrating apparatuses. One is that in order to minimize Ohmic (resistant) electrical losses in generating the electric current, typically a number of photocells (synonymous with photovoltaic or solar cells) are electrically connected in series to produce a higher voltage output. However, this means that all the cells have their photocurrents limited by the cell with the weakest current due to the serial arrangement. The individual photocurrents vary with the size of the active/illuminated area, the quality of the photovoltaic semiconductors in the individual cells, and the non-uniformity of the illumination which is characteristic of such concentrators due to optical non-uniformities. Note that the last is a particular problem since optical uniformity of the light beam at the focal point of the optical system is often poor.

Typically these problems, while recognized, have been addressed by developing individual optics for each photocell in the array, such as a set of lenses such as Fresnel lens or other types of lens, or by otherwise correcting the optics, that is tuning the optics individually to try to make the focal plane of the optical system as uniform and aberration-free as possible. Of course both of these solutions involve relatively expensive optics and can make mass production difficult.

The technical problem can be characterized as imaging a circular object (the sun) on what is, in the prior art, a square solar cell array. Aspects of the present disclosure are intended to use the light beam energy more efficiently to maximize the efficiency of the solar cell array.

So the present system, referred to here as a photo-current balancing system, in some embodiments uses a photocell arrangement which complements any optical system aberrations rather than trying to eliminate such aberrations. In one embodiment, an optical system with circular symmetry is matched with a photocell array in the general shape of a circle or polygon divided into wedges, such as slices of a pie. Each wedge is one photocell. The photo-currents may be balanced by displacing the illumination centroid near the center of the pie shaped array using feedback from the array, and accordingly mechanically moving the solar cell array.

Another embodiment matches the photocell geometry to the Seidel aberrations of the optical system, that is the mirrors. The photocurrents are then balanced by adjusting, not only the centroid displacement, but also the defocus, astigmatism, and coma of the optical system by moving the solar cell array relative to the reflector (mirrors). This has the advantage of allowing for cost savings in constructing such a system since lower quality optics can be used without compromising system efficiency in terms of electrical current generation.

In one embodiment, the photocell array includes a plurality of triangular (wedge) shaped (in plan view) individual photocells which are otherwise of conventional construction. They are arranged like slices of a pie. Each slice (triangle) is of approximately the same surface area. The base of each slice may be curved as in a pie wedge or straight as in a triangle. The term “triangular” here generally refers to pie wedges, true triangles and similar shapes. Arranged peripherally around the central triangular shaped cells is a set of trapezoid shaped solar cells, each such trapezoidal cell having its narrower base adjacent the base of one of the triangular cells and its wider base spaced away from one of the triangular cells. Thus there is one trapezoidal cell for each triangular solar cell. In one embodiment, the trapezoidal cells are of a larger surface area than the central triangular cells since typically the light beam being provided from the optical system is less intense at the edge of the illumination spot.

Moreover in addition to the layout of the solar cells, the solar cell concentrator of which the solar cell array is one component, includes a support for the solar cell array. The support includes a cooling plate (heat sink) in thermal contact with the obverse side of the solar cells. In one version, the heat sink defines a set of channels through which a cooling fluid, such as water or air, or another fluid may circulate via a conventional manifold to prevent overheating of the solar cell array, due to the intense incident light beam. Suitable conventional electrical current conductors are provided electrically in contact with the solar cells, e.g., at their outer perimeters or undersides, as is conventional. Moreover the series/parallel electrical connections of the solar cells to one another may be configured to provide optimum voltage and current output.

### BRIEF DESCRIPTION OF THE DRAWINGS

FIGS. 1 and 2 show two respective prior art solar cell concentrators.

FIG. 3 shows a plan view of the present solar cell array.

FIG. 4 shows a plan view of one of the trapezoidal solar cells of the array of FIG. 3.

FIG. 5 shows a plan view of one of the triangular solar cells of the array of FIG. 3.

FIG. 6 shows a cross sectional view of the solar cell array of FIG. 3.

FIG. 7 shows an arrangement of the solar cells with feedback.

### DETAILED DESCRIPTION

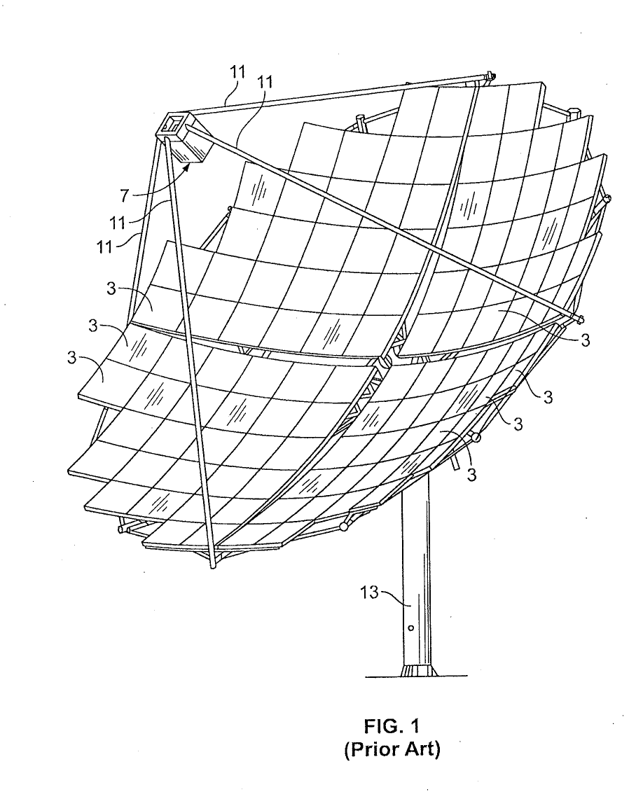

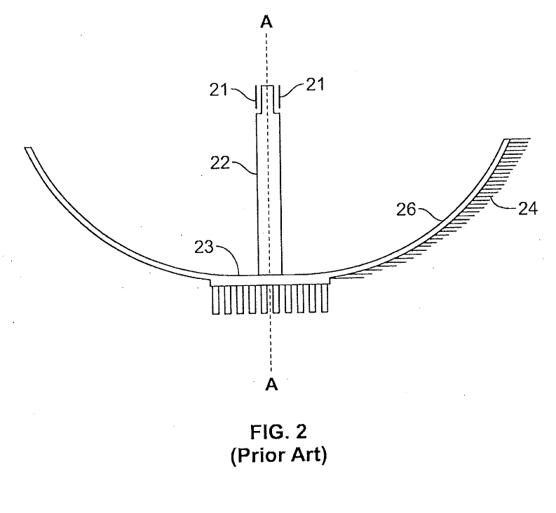

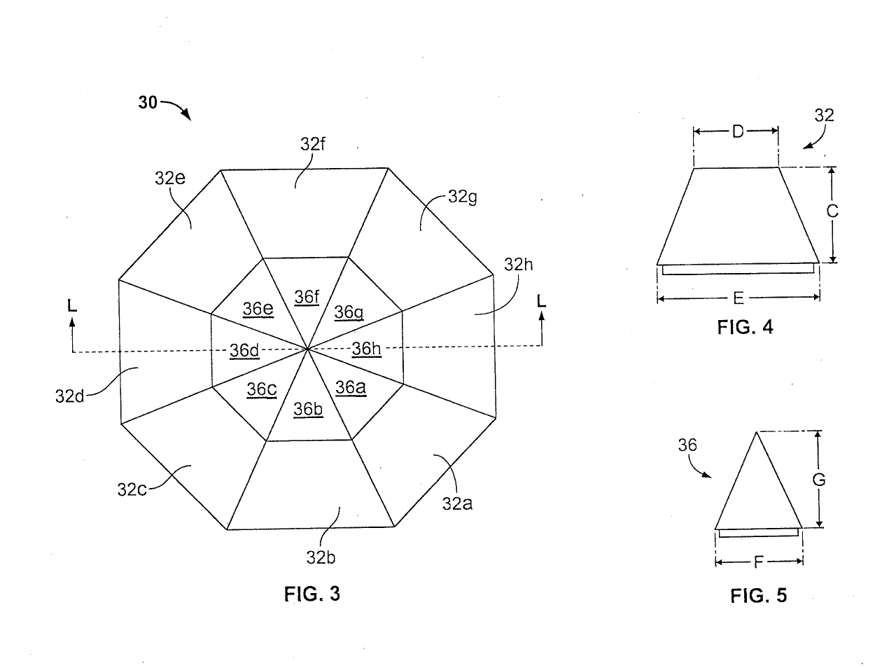

FIG. 3 shows in one embodiment the present solar cell array 30 in plan view as would face a reflector (mirror) structure similar to that of FIGS. 1 and 2. The mirror reflectors of FIG. 1 or 2 and the strut or struts which hold solar cell array 30 in position are not shown in FIG. 3 as being conventional. In this example solar cell array 30 includes a plurality of triangular shaped solar cells 36a-36h, arranged side by side to define an octagon. In this case there are eight such cells, so each defines in this case a 45° isosceles triangle. Arranged around the perimeter of the triangular shaped solar cells is a plurality of trapezoidal shaped solar cells 32a-32h, there being here one trapezoidal solar cell associated with each triangular solar cell. This one-to-one relationship is only exemplary. This depicts a 16 cell solar array. If these are 16 typical solar cells each outputting a current having a potential of about 2.6 volts, the total voltage output of all the cells when electrically connected in series is about 42 volts.

Detail of one of the triangular shaped solar cell is shown in FIG. 5, where dimensions G and F, are respectively in one (merely exemplary) embodiment 1.16 cm and 1.4 cm.

FIG. 4 shows a similar plan view of one of the trapezoidal cells 32, where the three dimensions C, D, and E are for example respectively 1.4 cm, 1.36 cm, and 2.32 cm.

The nature and number and composition and type of the individual solar cells are not limited here. They may be any type of conventional type solar cells, such as conventional mono or poly-crystalline (wafer type) solar cells, thin film solar cells, single junction photocells, multi-junction photocells, etc. The cells in any one array need not be of the same type. Hence the nature of the solar cells in terms of their semiconductor activity and electrical output is conventional here in terms of the individual cells. While cells having the triangular or trapezoidal shapes are not believed to be commercially available, cells of such shapes may be manufactured using conventional methods. Alternatively, although care must be taken to preserve electrical contact with the cell conductors, one may obtain commercially available square or rectangular shaped cells and conventionally saw (cut) them into the requisite shapes. For instance, one square shaped cell cut along its diagonal will provide two 90° isosceles triangular cells. Such square or rectangular cells are commercially available from a variety of vendors.

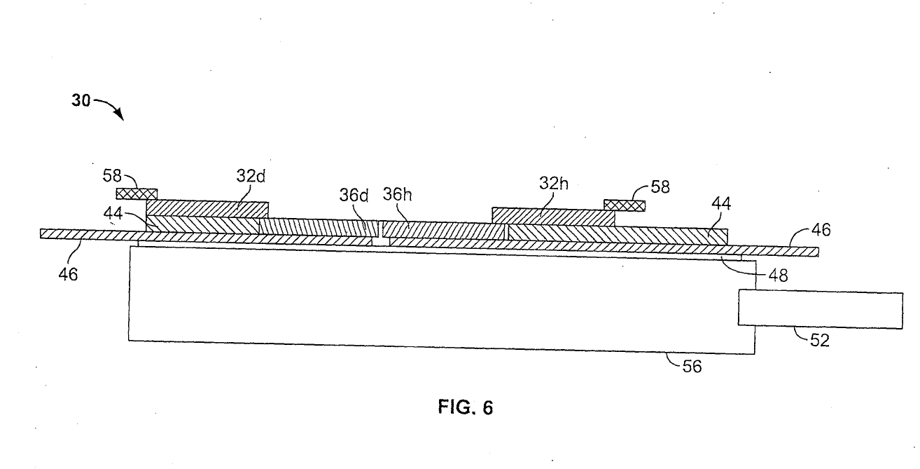

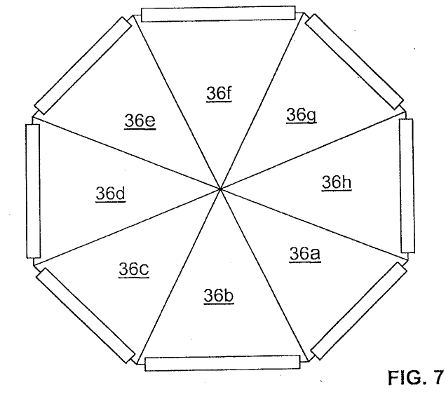

FIG. 6 shows a cross section along line L-L of solar cell array 30 of FIG. 3. FIG. 6 shows two of the triangular solar cells 36d, 36h and the two associated outer trapezoidal cells 32d, 32h. In this case the trapezoidal cells 32d, 32h are displaced in terms of their plane from the triangular cells 36d, 36h. The displacement is not required; it is used here for providing sufficient space for the electrical connections to each cell. Also shown here (but not in FIG. 3 for simplicity) are such conventional electrical current conductors 46 (e.g., bus bars) and 58 (e.g., metal coatings) in contact with respectively the triangular cells 36 and trapezoidal cells 32. A layer of thermally conducting electrical insulator 44 for example, metal oxide or silicone based heat sink compound, provides thermal contact to electrical conductor 46 for a heat path.

Electrical conductor 46 in turn conducts the heat into the heat sink 56, which is for instance an aluminum plate of suitable size and thickness depending on the expected heat load, to absorb the heat caused by the incident light on the solar cells. It is to be understood that the amount of heat so generated may be considerable. To aid in heat dissipation, in some embodiments heat sink 56 defines a number of internal channels or conduits (not shown) for carrying a cooling fluid, such as, e.g., air, water, or lithium bromide solution. In this case tubing bundle 52 is provided for conducting the cooling fluid into and out of the heat sink 56, for instance via a conventional manifold, to a radiator or perhaps to some sort of external co-generation system to use the heat productively, e.g., to operate air conditioning or provide hot water. In this example a clearance (spacing) 48 is provided between the cooling plate 56 and the lower conductor layer 46, but this is not required.

The absolute and relative size (surface area) of each cell is selected in some embodiments according to particular goals, as explained hereinafter. In one embodiment, the active surface area which in turn determines their current output is adjusted during design or construction of the apparatus to match the expected or measured non-uniformity of illumination in terms of local variations in the intensity of the incident light beam from the reflector assembly. It is known that both imaging and non-imaging solar collectors typically produce non-uniform illumination, which is more intense at the central region than along its periphery. So, as shown in FIG. 3 the outer cells have relatively larger surface areas than the inner cells. In other embodiments the light beam may exhibit a plurality of local intensity variations, and the cell surface area may be varied in a more complex fashion accordingly.

FIG. 3 depicts two concentric rings of cells, the inner triangular cells with the peripheral trapezoidal cells. A third set of cells may be provided located peripheral to the trapezoidal cells for an apparatus with a larger diameter light beam, in another embodiment. Further sets of cells may also be provided moving radially outward from the center of the cell array.

Also it has been found that a large number of relatively small mirrors as described above provides an advantageous low pass filtering effect adding to the above-described beam flattening effect.

In yet another aspect, in the solar cell array of FIG. 3 and as depicted in FIG. 7, the detected photocurrent (or a proxy for photocurrent such as the photo-voltage) from triangular photocell 36b is subtracted from the detected photocurrent of triangular photocell 36f to produce an error signal (using a suitable processor) that is used to mechanically drive the optical system (via suitable servo motors or by moving it manually) in such a way as to move the centroid of the illumination toward photocell 36f. Similarly, one could use a combination of photocell signals (i.e., the sum of currents from cells 36e, 36f, and 36g minus the sum of cells 36a, 36b, and 36c) to generate the error signal. This provides the above described feedback effect and also the above described defocus, astigmatism and coma corrections.

This disclosure is illustrative and not limiting; further modifications will be apparent to those skilled in the art in light of this disclosure and are intended to fall within the scope of the appended claims.

I claim:

1. A photovoltaic cell array adapted for receiving a beam of incident light, comprising:
a plurality of triangular photovoltaic cells arranged around a central region;
a plurality of trapezoidal photovoltaic cells arranged around the plurality of triangular cells;
a support for the cells; and
at least one electrical conductor in contact with each cell.

2. The cell array of claim 1, wherein the cell array is adapted to receive a beam of light more intense at the central region.

3. The cell array of claim 1, wherein one triangular cell is adjacent each trapezoidal cell.

4. The cell array of claim 3, wherein a surface area of each trapezoidal cell is greater than that of the adjacent triangular cell.

5. The cell array of claim 1, wherein each triangular cell defines an isosceles triangle.

6. The cell array of claim 1, wherein each triangular cell has a base length in the range of 0.5 to 2 cm, and a height in the range of 0.7 to 3 cm.

7. The cell array of claim 1, wherein each of the triangular cells is of approximately equal surface area.

8. The cell array of claim 1, wherein each of the trapezoidal cells is of approximately equal surface area.

9. The cell array of claim 1, wherein the support includes a heat sink.

10. The cell array of claim 1, wherein at least a portion of the heat sink is spaced apart from the cells.

11. The cell array of claim 1, wherein the triangular cells define a plane and the trapezoidal cells lie off the plane.

12. The cell array of claim 1, further comprising a first electrical conductor in contact with a surface of a plurality of the triangular cells and a second electrical conductor in contact with a surface of a plurality of the trapezoidal cells.

13. The cell array of claim 9, wherein the heat sink includes a thermally conductive and electrically insulative element in contact with a plurality of the cells.

14. The cell array of claim 9, the heat sink including a conduit for passage of a fluid.

15. The cell array of claim 1, wherein each cell is selected from the group consisting of monocrystalline cells, polycrystalline cells, thin film cells, light absorbing dye cells, organic cells, nanocrystalline cells, single junction cells, multi-band cells, and multi-junction cells.

16. The cell array of claim 2, wherein a surface of area of each cell is approximately an inverse linear function of an intensity of a portion of the light beam incident on that cell.

17. The cell array of claim 1, wherein the triangular cells have a straight or curved base edge.

18. A solar concentrator apparatus comprising:
an optical collector assembly adapted to form incident sunlight into a beam of light; and
a photovoltaic cell array located to receive the beam of light and including:
a plurality of triangular photovoltaic cells arranged around a central region;
a plurality of trapezoidal photovoltaic cells arranged around the plurality of triangular cells;
a support for the cells; and
at least one electrical conductor in contact with each cell.

19. The apparatus of claim 18, wherein the collector assembly includes a parabolic or concave reflector.

20. The apparatus of claim 18, wherein the collector assembly includes a plurality of planar reflectors.

21. The apparatus of claim 18, wherein the collector assembly includes a single reflective surface.

22. The apparatus of claim 18, further comprising a circuit coupled to a plurality of the cells and adapted to process detected photo currents from a plurality of the solar cells and providing a signal to move the collector assembly so as to move the collector assembly relative to the beam of light.
